(19) United States
(12) Patent Application Publication
(10) Pub. No.: US 2024/0196752 A1
(43) Pub. Date: Jun. 13, 2024

(54) METHOD FOR PRODUCING MAGNETOSTRICTIVE MATERIAL, MAGNETOSTRICTIVE MATERIAL, AND METHOD FOR PRODUCING ENERGY CONVERSION MEMBER

(71) Applicants: TOHOKU UNIVERSITY, Sendai-shi, Miyagi (JP); TOHOKU STEEL CO., LTD., Shibata-gun, Miyagi (JP)

(72) Inventors: Hiroki KURITA, Sendai-shi (JP); Fumio NARITA, Sendai-shi (JP); Kenya NAKAJIMA, Sendai-shi (JP); Masahito WATANABE, Shibata-gun (JP); Takenobu SATO, Shibata-gun (JP); Takashi EBATA, Shibata-gun (JP)

(73) Assignees: TOHOKU UNIVERSITY, Sendai-shi, Miyagi (JP); TOHOKU STEEL CO., LTD., Shibata-gun, Miyagi (JP)

(21) Appl. No.: 18/286,949

(22) PCT Filed: Mar. 11, 2022
(86) PCT No.: PCT/JP2022/011109

§ 371 Date: Oct. 13, 2023

(30) Foreign Application Priority Data
Apr. 13, 2021 (JP) 2021-067990

(51) Int. Cl. H10N 35/01; B22F 10/25; B23K 26/342; B23K 103/02; B33Y 10/00; B33Y 70/00; B33Y 80/00; H10N 35/85

(52) U.S. Cl. CPC H10N 35/01; B22F 10/25; B23K 26/342; B33Y 70/00; B33Y 80/00; B23K 2103/02; B33Y 10/00; H10N 35/85

(57) ABSTRACT

A method for producing a magnetostrictive material producible without using a mold, a magnetostrictive material, and a method for producing an energy conversion member; the first method includes melting raw material powder for the magnetostrictive material by a laser or electron beam using a metal 3D additive manufacturing machine to perform additive manufacturing. The raw material powder is composed of an Fe—Co alloy. A method for producing an energy conversion member includes laminating and joining one of a magnetostrictive layer formed by melting raw material powder for a magnetostrictive material by a directed energy deposition method to perform additive manufacturing and a soft magnetic material layer formed by melting raw material powder for a soft magnetic material by the directed energy deposition method to perform additive manufacturing on another.

### FIELD OF THE INVENTION

The present invention relates to a method for producing a magnetostrictive material, a magnetostrictive material produced by the production method, and a method for producing an energy conversion member using a magnetostrictive material.

### DESCRIPTION OF RELATED ART

Conventionally, as a method for producing a magnetostrictive material, there has been known a method in which an alloy material that becomes a magnetostrictive material is subjected to hot working and then to cold working (for example, see Patent Literature 1).

Incidentally, recently, an additive manufacturing technique has attracted attention. For example, a magnetically anisotropic lamination forming method is disclosed. In the method, in order to form a magnet having any shape and magnetic anisotropy in any direction without using a mold, magnetically anisotropic granules oriented in a magnetically anisotropic manner are intermittently supplied at 1 Hz to 10 Hz on a table moving in three directions of XYZ in a magnetic field as three-dimensionally designed and fixed to it by a laser beam (for example, see Patent Literature 2).

### CITATION LIST

### Patent Literature

Patent Literature 1: WO 2015/083821
Patent Literature 2: JP-A-2015-141964

### SUMMARY OF THE INVENTION

### Technical Problem

However, in the method for producing a magnetostrictive material described in Patent Literature 1, there has been a problem that, when a magnetostrictive material is formed using a mold, it is necessary to manufacture a mold to fit the shape of the magnetostrictive material, therefore requiring manufacturing man hours and manufacturing cost. While the formation of a magnet by the additive manufacturing technique as described in Patent Literature 2 has been known, the additive manufacturing technique has not been used to produce a magnetostrictive material.

A magnetostrictive material is used for utilizing deformation caused by magnetostriction of the material or an inverse magnetostriction effect caused by the deformation. The magnetostrictive material does not become a practical energy conversion member unless it develops anisotropy in which the deformation in a certain direction or the inverse magnetostriction effect becomes large. In order to develop anisotropy when being shaped, directionality of a magnetostrictive property should be controlled. However, it has not been considered that the anisotropy can be achieved even if additive manufacturing is performed using a raw material for a magnetostrictive material.

The present invention has been made by paying attention to such problems, and an object of the present invention is to provide a method for producing a magnetostrictive material producible without using a mold, a magnetostrictive material, and a method for producing an energy conversion member.

### Solutions to the Problems

In order to solve the above-mentioned problems, a method for producing a magnetostrictive material according to the present invention includes melting raw material powder for a magnetostrictive material by a directed energy deposition method to perform additive manufacturing.

With the method for producing a magnetostrictive material according to the present invention, a magnetostrictive material is producible without using a mold. In addition, a magnetostrictive material having three-dimensional magnetic anisotropy can be produced.

The method for producing a magnetostrictive material according to the present invention preferably includes melting the raw material powder by a laser or electron beam using a metal 3D additive manufacturing machine to perform additive manufacturing.

The method for producing a magnetostrictive material according to the present invention preferably includes a step of cutting a laminated magnetostrictive material in a predetermined direction.

In this case, a magnetostrictive material that has different properties depending on the cutting direction can be produced.

The raw material powder is preferably composed of an Fe—Co alloy.

In the method for producing a magnetostrictive material according to the present invention, the raw material powder may be subjected to additive manufacturing into a honeycomb structure. In this case, an output power density per unit volume of the produced magnetostrictive material can be enhanced.

The magnetostrictive material according to the present invention is produced by the above-described method for producing a magnetostrictive material and has a honeycomb structure. The magnetostrictive material has an enhanced output power density per unit volume.

A method for producing an energy conversion member according to the present invention includes laminating and joining one of a magnetostrictive layer formed by melting raw material powder for a magnetostrictive material by a directed energy deposition method to perform additive manufacturing and a soft magnetic material layer formed by melting raw material powder for a soft magnetic material by the directed energy deposition method to perform additive manufacturing on another.

With the method for producing an energy conversion member according to the present invention, a magnetostrictive material and a soft magnetic material are producible without using a mold, and joining of them can be performed by laminating one of them on the other.

The energy conversion member produced by the method for producing an energy conversion member according to the present invention can generate an induced current in the pickup coil by an inverse magnetostriction effect of the magnetostrictive material due to vibration if a pickup coil is disposed nearby.

Preferably, the raw material powder for the magnetostrictive material is composed of an Fe—Co alloy, and the raw material powder for the soft magnetic material is composed of an alloy of Ni and 0 mass % to 20 mass % Fe or Ni—Co alloy.

Another method for producing an energy conversion member according to the present invention includes laminating and joining a magnetostrictive layer formed by melting raw material powder for a magnetostrictive material by a directed energy deposition method to perform additive manufacturing on a soft magnetic material. The soft magnetic material is preferably composed of an elongated plate-shaped alloy of Ni and 0 mass % to 20 mass % Fe or Ni—Co alloy.

The present invention can provide a method for producing a magnetostrictive material that can produce a magnetostrictive material without using a mold, a magnetostrictive material, and a method for producing an energy conversion member.

### BRIEF DESCRIPTION OF THE DRAWINGS

FIG. 1(a) is an SEM image of Fe—Co powder used in a method for producing a magnetostrictive material according to an embodiment of the present invention, and FIG. 1(b) is an explanatory view of a scanning direction and a building direction used in the production method.

FIGS. 2(a), 2(b), and 2(c) are magnetostriction-magnetic field curves in x-y planes, y-z planes, and z-x planes of additively manufactured Fe—Co alloys, respectively, in Example 1 of the present invention, and FIGS. 2(d), 2(e), and 2(f) are B—H curves in the x-y planes, the y-z planes, and the z-x planes of the additively manufactured Fe—Co alloys, respectively.

FIGS. 3(a), 3(b), and 3(c) are graphs illustrating anisotropy energies ΔK1 on the x-y planes, the y-z planes, and the z-x planes of the additively manufactured Fe—Co alloys, respectively, in Example 1 of the present invention, FIGS. 3(d), 3(e), and 3(f) are graphs illustrating piezomagnetic constants d in the x-y planes, the y-z planes, and the z-x planes, respectively, and FIGS. 3(g), 3(h), and 3(i) are graphs illustrating the maximum piezomagnetic constants in the x-y planes, the y-z planes, and the z-x planes, respectively.

FIG. 4(a) is a graph illustrating X-ray diffraction method (XRD) patterns of a rolled material and an additively manufactured alloy (300 W) (y-z plane) in Example 1 of the present invention, and FIGS. 4(b) and 4(c) are graphs illustrating full widths at half maximum (FWHM) calculated from the X-ray diffraction method patterns of the rolled material and the additively manufactured alloy (300 W) (y-z plane), respectively.

FIGS. 5(a), 5(b), and 5(c) are kernel average misorientation (KAM) maps and inverse pole figure (IPF) maps of the rolled material, the alloy (300 W) (x-y plane), and the alloy (300 W) (y-z plane), respectively, which exhibit fine structures obtained by an EBSD analysis in Example 1 of the present invention, and FIGS. 5(d), 5(e), and 5(f) are high-resolution KAM maps and IPF maps of the rolled material, the alloy (300 W) (x-y plane), and the alloy (300 W) (y-z plane), respectively.

FIG. 6 is a graph illustrating a relationship between a laser energy density and a relative density of an additively manufactured alloy in Example 1 of the present invention.

FIG. 7(a) is an explanatory view illustrating a configuration of experimental equipment used in Example 2 of the present invention, FIG. 7(b) is a graph illustrating output power densities per unit volume of a magnetostrictive material having a honeycomb structure additively manufactured in Example 2 and a normal plate-shaped magnetostrictive material, and FIG. 7(c) is a side view illustrating each specimen of the normal plate-shaped magnetostrictive material and the magnetostrictive material having a honeycomb structure used in the experiment.

FIG. 8(a) illustrates Fe52-Co48 alloy cubes produced using various parameters in Example 3 of the present invention, and FIG. 8(b) is a schematic diagram illustrating a scanning method used.

FIG. 9(a) is a schematic diagram of a vibration-energy-harvesting performance test, and FIG. 9(b) is a schematic diagram of an impact-energy-harvesting performance test.

FIG. 10 illustrates XRD patterns of the Fe52-Co48 alloy cubes obtained using each production parameter.

FIG. 11 illustrates a secondary electron image and EDX maps of the Fe52-Co48 alloy cube produced using P2V1 parameters.

FIG. 12 is a graph illustrating a relationship between a porosity and an energy density of the Fe52-Co48 alloy cubes produced with each parameter set.

FIG. 13 is an appearance photograph of Fe52-Co48 alloy plates having a (a) fully dense structure and a (b) honeycomb structure produced using the P2V1.

FIG. 14(a) is a graph illustrating relationships of output voltage to frequency of the Fe52-Co48 alloy plates having a fully dense structure and a honeycomb structure in the vibration-energy-harvesting tests, and FIG. 14(b) is a graph illustrating relationships of power density to resistance at resonant frequencies of the respective alloy plates.

FIG. 15 is a graph illustrating power densities of the Fe52-Co48 alloy plates having a fully dense structure and a honeycomb structure in the impact-energy-harvesting performance test.

### MODE FOR CARRYING OUT THE INVENTION

The following describes embodiments of the present invention.

In a method for producing a magnetostrictive material of an embodiment of the present invention, raw material powder for a magnetostrictive material is melted by a laser or electron beam using a metal 3D additive manufacturing machine to perform additive manufacturing. The output of the laser or electron beam may be varied. In addition, the speed of lamination may be varied. The metal 3D additive manufacturing machine is used for additively manufacturing a metal by a directed energy deposition (DED) method.

As the raw material powder for a magnetostrictive material, an Fe—Co alloy can be used. Since the Fe—Co alloy is low in cost, it is available as a magnetostrictive material intended for energy harvesting and sensors. The Fe—Co alloy exhibits a medium degree of magnetostriction of 80 ppm to 140 ppm, competitively low cost, and excellent mechanical characteristics. The Fe—Co alloy can be worked into rods, plates, and wires.

With the method for producing a magnetostrictive material, a magnetostrictive material is producible without using a mold. In addition, a magnetostrictive material having three-dimensional magnetic anisotropy can be produced. Furthermore, it is possible to shape into a complex shape or structure. After-treatment such as rolling and heat treatment performed after conventional production need not be performed after additive manufacturing processing.

A process of cutting a laminated magnetostrictive material in a predetermined direction may be included. A magnetostrictive material that has different properties depending on the cutting direction can be produced.

The raw material powder for a magnetostrictive material is composed of, for example, an Fe—Co alloy. Raw material powder for a soft magnetic material is composed of, for example, an alloy of Ni and 0 mass % to 20 mass % Fe or Ni—Co alloy.

An additively manufactured Fe—Co alloy has more excellent magnetostriction performance than a hot rolled Fe—Co alloy. For example, an anisotropy energy ΔK1 of an Fe—Co alloy (alloy (300 W)) obtained with a laser output power of 300 W is larger than an anisotropy energy of a rolled material. When y is a scanning direction and z is a building direction, a piezomagnetic constant d of the alloy (300 W) with respect to a y-z plane is large irrespective of a magnetic field direction, which is 340 pm/A. The alloy (300 W) with respect to the y-z plane has low lattice strain compared with the rolled material and has high lattice strain in a <200> plane. This means that it has significantly few lattice defects, such as dislocations of an additively manufactured alloy, compared with a rolled material. Accordingly, for a low piezomagnetic constant d, magnetic domain transfer in the alloy is considered to be difficult.

The piezomagnetic constant d in a specific direction of the additively manufactured Fe—Co alloy is three times or more larger than that of the rolled material. Furthermore, elongated voids formed during additive manufacturing change the magnetostriction performance in a direction perpendicular to these voids. The additively manufactured Fe—Co alloy is applicable as a force sensor for the Internet of things (IOT) that needs to be highly responsive.

In the method for producing a magnetostrictive material of an embodiment of the present invention, the raw material powder for a magnetostrictive material may be subjected to additive manufacturing into a honeycomb structure. In this case, an output power density per unit volume of the produced magnetostrictive material can be enhanced.

A magnetostrictive material of an embodiment of the present invention is produced by the above-described method for producing a magnetostrictive material and has a honeycomb structure. The magnetostrictive material has an enhanced output power density per unit volume.

In a method for producing an energy conversion member of an embodiment of the present invention, a magnetostrictive layer formed by melting raw material powder for a magnetostrictive material to perform additive manufacturing is laminated and joined on a soft magnetic material layer formed by melting raw material powder for a soft magnetic material by a directed energy deposition method to perform additive manufacturing using a metal 3D additive manufacturing machine. Alternatively, the soft magnetic material layer is laminated and joined on the magnetostrictive layer.

With the method for producing an energy conversion member, a magnetostrictive material and a soft magnetic material are producible without using a mold, and joining of them can be performed by laminating one of them on the other. The produced energy conversion member is, for example, shaped into an elongated plate shape and used by having one end attached to a resonance generator or the like in a cantilever manner. By disposing a pickup around the energy conversion member, an induced current can be generated in the pickup by the inverse magnetostriction effect of the magnetostrictive material due to vibration, allowing the energy conversion member with the pickup to be utilized as a power generation device or sensor. The pickup can be configured by, for example, a coil inside which the energy conversion member is arranged.

Instead of laminating and joining the magnetostrictive layer on the soft magnetic material layer formed by additive manufacturing, the magnetostrictive layer may be laminated and joined on a soft magnetic material prepared in advance. The soft magnetic material is, for example, composed of an elongated plate-shaped alloy of Ni and 0 mass % to 20 mass % Fe or Ni—Co alloy.

### Example 1

### [Experimental Method]

Fe30-Co70 magnetostrictive material powder having an average grain size of 120 μm or more was produced by gas atomization. However, in a used metal 3D additive manufacturing machine (DED machine) (“Mobile 1.0” manufactured by BeAM, France), particles having a size of less than 105 μm, ideally 40 μm to 90 μm are required. Accordingly, the magnetostrictive material powder as first powder was crushed with a ball mill under conditions described in Table 1 to decrease the particle size from 120 μm to 45 μm.

TABLE 1

| Ball size | ϕ10 | mm |
|---|---|---|
| Ball weight before milling | 1200 | g |
| Weight of first powder | 135 | g |
| Process control agent (PCA) | 135% | |
| Milling gas | Ar | |
| Milling cycles | 9 | times |
| Speed | 350 | rpm |
| Interval | 10 | min |
| Break | 10 | min |
| Direction of rotation | Up milling | |
| Milling process time | 3 | hr |

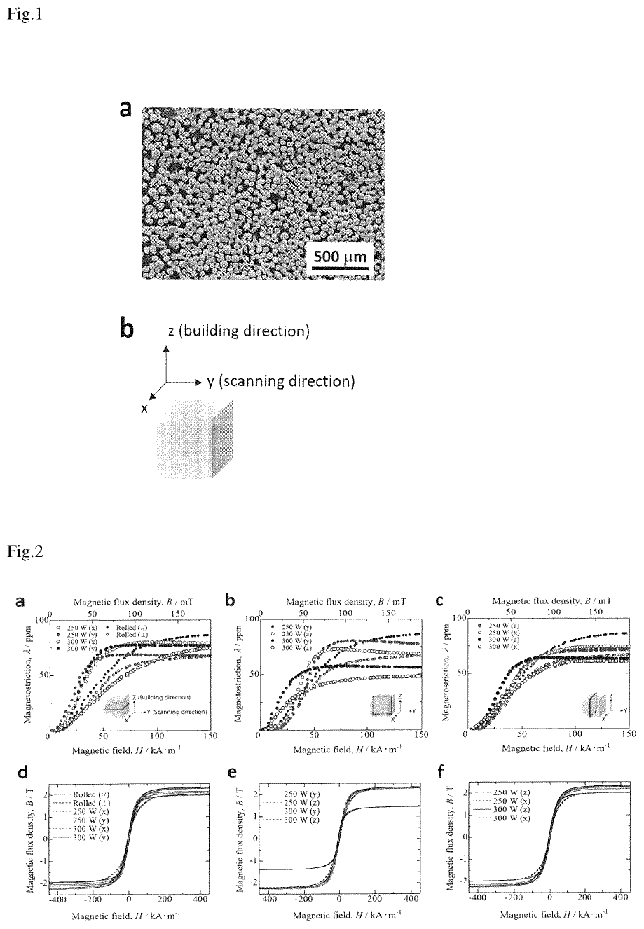

As a result of observing the obtained particles with a scanning electron microscope (SEM), the average particle size was approximately 45 μm as illustrated in FIG. 1(a). Next, additive manufacturing was performed with the prepared magnetostrictive material powder using the metal 3D additive manufacturing machine (“Mobile 1.0” manufactured by BeAM, France). Fe—Co alloys of 1×1×1 cm³ were produced on a steel plate (316 L, thickness of 1 cm) in the DED machine under a controlled atmosphere (O₂<10 ppm, H₂O<150 ppm). Printing conditions were hatch space of 0.56 mm, scanning speed of 1000 mm/min, and layer thickness of 0.2 mm. Laser output power was set to 200 W, 250 W, and 300 W. The 200 W, 250 W, and 300 W correspond to 107.1 J/mm³, 133.9 J/mm³, and 160.7 J/mm³, respectively.

The scanning direction and the building direction were a y-direction and a z-direction, respectively (see FIG. 1(b)). A supply speed of the powder was maintained at 4 g/min for all the laminated structures. Densities of the produced Fe—Co alloys were measured by the Archimedes method. Crystalline structures, orientation, and particle sizes were evaluated in xy, yz, and zx planes after being treated with an ion milling (“IM4000” manufactured by Hitachi, Ltd.) using an SEM (SU-70 manufactured by Hitachi, Ltd.) and electron backscatter diffraction (EBSD).

In order to measure magnetic properties and magnetostrictive properties, the alloys were cut in each plane (x-y, y-z, z-x) and polished to a width of approximately 6×6 mm² and a thickness of approximately 0.2 mm. However, an x-y plane of the Fe—Co alloy obtained at 200 W (hereinafter referred to as “alloy (200 W)”) was difficult to measure because many cracks were generated in the polishing process. For comparative measurement, a hot rolled Fe30-Co70 alloy was prepared.

The magnetostrictive properties and crystalline structures of the additively manufactured Fe—Co alloys were examined by an XRD method, and saturation magnetization, remanent magnetization, and coercivity were measured using a vibrating sample magnetometer (VSM “BHV-50H” manufactured by Riken Denshi Co., Ltd.). Similarly to the case of the EBSD, magnetostriction was measured by a strain gauge method of applying a magnetic field to each direction (x-y, y-z, and z-x planes) in parallel and perpendicularly and using a two-axis gauge. The results obtained by the VSM measurement were used to also calculate magnetic anisotropy energies. [Results]

The properties of the Fe—Co alloys obtained at 250 W and 300 W (which are hereinafter referred to as “alloy (250 W)” and “alloy (300 W)”) and the hot rolled Fe—Co alloy were examined. Table 2 shows the density measurement results of the respective alloys. Fe—Co has a theoretical density of 8.58 g/cm³. However, the densities of all the additively manufactured Fe—Co alloys obtained by the DED were smaller than the theoretical value.

TABLE 2
Density of Fe₃₀Co₇₀ Calculated theoretical density is 8.58 g/cm³

| | Energy | | |
|---|---|---|---|
| Laser power | density | Density | Error |
| (W) | (J/mm³) | (g/cm³) | (%) |
| 200 | 107.1 | 7.60 | 10.9 |
| 250 | 133.9 | 7.72 | 9.5 |
| 300 | 160.7 | 7.85 | 8.0 |

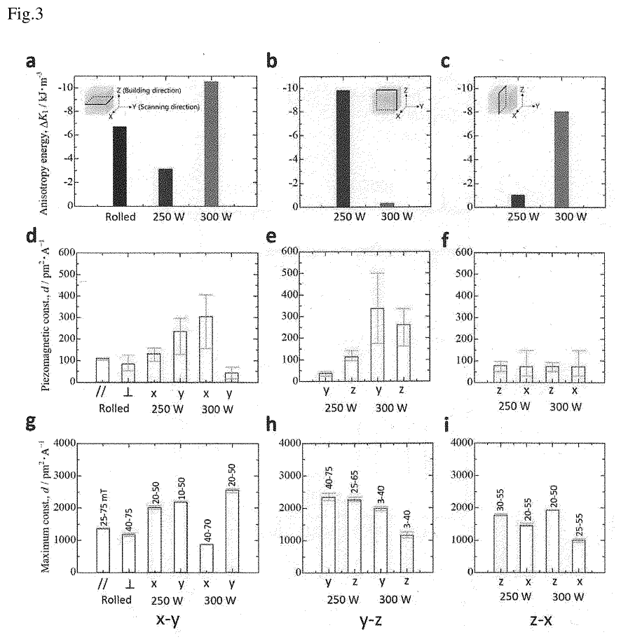

FIG. 2a is a result of magnetostriction-magnetic field curves with respect to the x-y planes of the additively manufactured Fe—Co alloys. The curve of the Fe—Co alloy (250 W) has an initial gradient larger than that of the rolled alloy. In the case of a one-dimensional problem, constituent equations of the magnetostrictive material are shown below:

ε=sσ+d′H (1)

B=d′σ+μH (2)

where σ and ε are a stress and a strain, B and H are a magnetic-flux density and a magnetic field intensity, and s, d′, and μ are an elastic compliance coefficient, a magnetoelastic constant, and a magnetic permeability, respectively. The magnetoelastic constant is provided by d′=d+mH (d is a piezomagnetic constant, and m is a secondary magnetoelastic constant). The inclination of a curve represents the piezomagnetic constant d as a parameter directly related to the performance of a magnetostrictor. Therefore, an additively manufactured Fe—Co alloy is considered to exhibit more excellent performance as the magnetostrictor than a conventional hot rolled Fe—Co alloy.

Further, it was indicated that the initial gradient of the Fe—Co alloy (250 W) under the magnetic field in the y-direction was larger than the initial gradient under the magnetic field in an x-direction. The result of the Fe—Co alloy (300 W) indicates that increasing the output decreases the initial gradient irrespective of the direction of the applied magnetic field. For the Fe—Co alloy (250 W), the size of the magnetic field that allows the magnetostriction to reach saturation is far smaller than that of the magnetostriction of the rolled material. A similar trend is observed for the Fe—Co alloy (300 W) under the magnetic field in the y-direction. However, for the Fe—Co alloy (300 W) under the magnetic field in the x-direction, the magnetostriction increases linearly with an increase in the magnetic field and does not saturate at less than 150 kA/m. The magnetostriction of the Fe—Co alloy (250 W) under the magnetic field in the y-direction is lower than the magnetostriction of the Fe—Co alloy (250 W) under the magnetic field in the x-direction and the magnetostriction of the Fe—Co alloy (300 W) under the magnetic field in the x-direction and the y-direction.

FIG. 2b illustrates a similar result with respect to the y-z planes. For the y-z plane, the curve of the Fe—Co alloy (300 W) has an initial gradient far larger than the initial gradients of the curves of the Fe—Co alloy (250 W) and the rolled alloy. Next, the output increases the inclination of the curve. However, the output reduces the magnetostriction. FIG. 2c illustrates a similar result with respect to the z-x planes. Similarly to the Fe—Co alloy (300 W) in the x-y plane under the magnetic field in the x-direction, the magnetostriction of the Fe—Co alloy (300 W) under the magnetic field in the x-direction increases linearly with an increase in the magnetic field. Afterwards, the magnetostriction gradually saturates. FIGS. 2d, 2e, and 2f illustrates B—H curves in the x-y planes, the y-z planes, and the z-x planes, respectively.

FIG. 3a illustrates the anisotropy energies ΔK1 in the x-y planes of the additively manufactured Fe—Co alloys. For comparison, it illustrates the result of the rolled material. The anisotropy energy ΔK1 of the Fe—Co alloy (300 W) is larger than the anisotropy energy of the rolled material. FIGS. 3b and 3c illustrates the results with respect to the y-z planes and the z-x planes of the additively manufactured Fe—Co alloys. In contrast to the x-y plane, an anisotropy energy E in the y-z plane of the Fe—Co alloy (300 W) is smaller than the anisotropy energy of the rolled material. FIGS. 3d, 3e, and 3f illustrates the piezomagnetic constants d in the x-y planes, the y-z planes, and the z-x planes, respectively.

FIG. 3d illustrates the result of the rolled material. The piezomagnetic constant d of the rolled material under the magnetic field in a rolling direction is approximately 110 pm/A. On the other hand, the piezomagnetic constant d is 80 pm/A under the magnetic field in a direction perpendicular to the rolling direction. In the x-y plane, the piezomagnetic constant d of the Fe—Co alloy (300 W) under the magnetic field in the x-direction is maximum (approximately 300 pm/A), whereas the piezomagnetic constant d of the Fe—Co alloy (300 W) under the magnetic field in the y-direction is minimum (approximately 40 pm/A). This is because the anisotropy energy is high. In the y-z plane, the values of the piezomagnetic constant d of the Fe—Co alloy (300 W) are large in both the y-direction and the z-direction (340 pm/A and 260 pm/A, respectively). This is because the anisotropy energy is small. The Fe—Co alloy (300 W) has an anisotropic magnetostrictive property in the x-y plane and an isotropic magnetostrictive property in the y-z plane.

FIGS. 3g, 3h, and 3i illustrates maximum piezomagnetic constants d (maximum values of the constants d) corresponding to FIGS. 3d, 3e, and 3f, respectively. Values in the graphs are magnetic-flux density values at which inclinations become maximum. The maximum piezomagnetic constants d of the additively manufactured Fe—Co alloys are larger than the maximum piezomagnetic constant d of the rolled material. The magnetic-flux density values at which d exhibits the maximum value are small in both the y-direction and the z-direction in the y-z plane of the Fe—Co alloy (300 W).

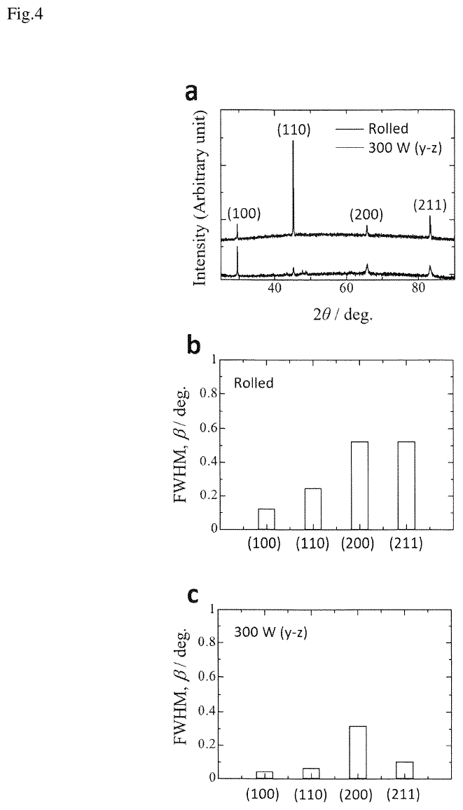

FIG. 4a illustrates X-ray diffraction method (XRD) data with respect to the rolled material and the alloy (300 W) in the y-z plane. Peaks of bcc structures for the respective alloys are detected. In the rolled material, a <100> plane is dominant, and a <110> plane is dominant in the alloy (300 W) in the y-z plane. Lattice constants of the rolled one and the alloy (300 W) in the y-z plane are calculated from the x-ray diffraction method patterns and are 0.2835 nm and 0.2839 nm, respectively. A full width at half maximum (FWHM) β is obtained as follows:

β=KΛ/D cos θ (3)

Here, K is a form factor (Scherrer constant), Λ is the wavelength of an X-ray (1.5418 Å for CuKα radiation), D is a crystal size in the unit of nanometer, and θ is the peak center. Strain induced in the powder by crystal imperfection and distortion can be estimated from the full width at half maximum (FWHM). FIGS. 4b and 4c illustrate the FWHMs B of the rolled material and the alloy (300 W) in the x-y plane, respectively. The alloy (300 W) (y-z plane) has low lattice strain compared with the rolled material, and each sample has high lattice strain in the <200> plane. This means that an alloy produced by additive manufacturing has significantly few lattice defects, such as dislocations, compared with a rolled material. Accordingly, it can be explained that a low piezomagnetic constant d makes magnetic domain transfer in the alloy difficult.

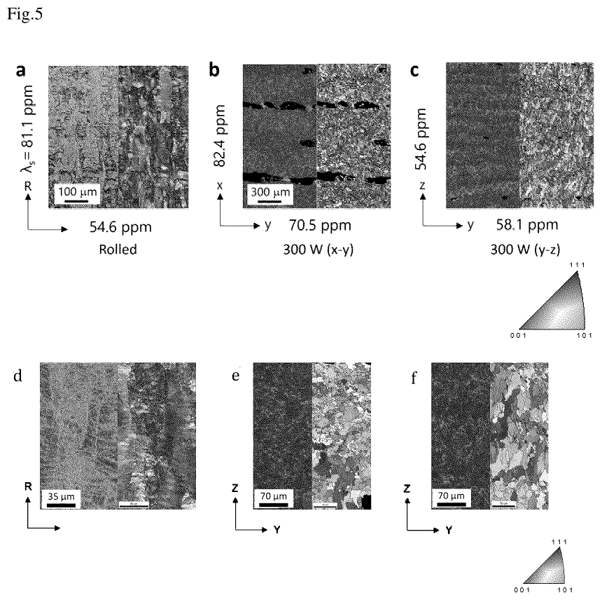

FIG. 5a illustrates a kernel average misorientation (KAM) map and an inverse pole figure (IPF) map obtained from the EBSD analysis of the rolled material. Magnetostrictions λs=(⅔)*(λ/−λ⊥) in parallel and perpendicular to the rolling direction are also indicated. A fine structure extends in the rolling direction, and the magnetostriction is larger than that in a plane perpendicular to the preferred orientation. FIGS. 5b and 5c illustrates similar results with respect to the alloy (300 W) in the x-y plane and the y-z plane, respectively. For the alloy (300 W) in the x-y plane, an advanced crystalline orientation is not observed.

From the KAM map and the IPF map, since hatch spacing of the interface between two subsequent layers is too large, voids are preferentially oriented in the y-direction (scanning direction). Since deformation due to the magnetic field in the x-direction should be small by the presence of the voids in the y-direction, the piezomagnetic constant d under the magnetic field in the x-direction (see FIG. 5d) is larger than the piezomagnetic constant d under the magnetic field in the y-direction. These voids are considered to contribute to the magnetostriction in the x-direction. The magnetostriction in the x-direction is at the same level as that of the rolled material. For the alloy (300 W) in the y-z plane, the KAM map indicates that strong distortion exists near a grain boundary. The distortion in the y-direction contributes to an increase in the piezomagnetic constant d under the magnetic field in the y-direction (see FIG. 5e) and an increase in the magnetostriction in the y-direction. From the IPF map, it can be confirmed that a pillar-shaped crystalline structure grows in the z-direction (building direction).

TABLE 3

| | | | Saturation | Remanent | |
|---|---|---|---|---|---|
| | | | magnetization | magnetization | Coercivity |
| Sample | Plane | Direction | (T) | (T) | (kA/m) |
| Rolled | — | R_{∥} | 2.26 | 0.20 | 5.40 |
| | | R_{⊥} | 2.30 | 0.22 | 5.07 |
| 300 W | x-y | x | 2.02 | 0.12 | 3.32 |
| | | y | 1.97 | 0.15 | 3.12 |
| | y-z | y | 1.42 | 0.11 | 3.09 |
| | | z | 1.42 | 0.13 | 3.08 |
| | z-x | z | 2.01 | 0.13 | 2.96 |
| | | x | 2.02 | 0.12 | 3.15 |

Table 3 summarizes the results of magnetic measurement of the rolled one and the additively manufactured alloy (300 W).

The alloy (300 W) exhibits low saturation magnetization compared with the rolled material, and the saturation magnetization in the y-z plane is especially low. In addition, the alloy (300 W) exhibits lower remanent magnetization and coercivity than the rolled material. This means that since the coercivity is low, these samples can be used for low magnetic field sensors.

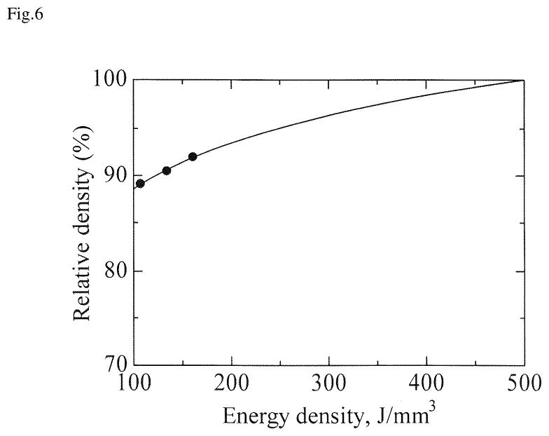

It seems that the alloy (300 W) has a density closest to the theoretical value. A high input energy density is required to obtain a high relative density. From a relationship between the energy density and the relative density as illustrated in FIG. 6, it is considered that a completely high-density alloy is obtained with an energy density of 500 J/mm³. In order to increase the energy density, it is necessary to reduce scan speed, hatch spacing, and layer thickness.

The Fe—Co alloys were additively manufactured using the DED system with various energy densities, and the magnetostrictive properties and the magnetic properties of the Fe—Co alloys were clarified. As a result, it was indicated that their magnetostrictive properties depended on the building direction, scanning direction, and surface orientation. Furthermore, voids formed during additive manufacturing (AM) increase or reduce the magnetostrictive properties of the additively manufactured Fe—Co alloys depending on the direction. For the alloy (300 W) in the y-z plane, the piezomagnetic constant d was large irrespective of the magnetic field direction, which was approximately 340 pm/A. This result indicates that it is three times or more larger than that of the rolled material. For the alloy (300 W) in the x-y plane, the piezoelectric constant d under the magnetic field in the x-direction is also three times or more larger than that of the rolled material, and the magnetostriction is almost equal to that of the rolled material. Since the coercivity is lowered from the result of the magnetic property evaluation, an additively manufactured Fe—Co alloy can be applied to, for example, an IoT sensor having a complex shape. The properties of the alloy produced by additive manufacturing can be further improved by controlling the structure of the alloy in one direction like a single crystal.

### Example 2

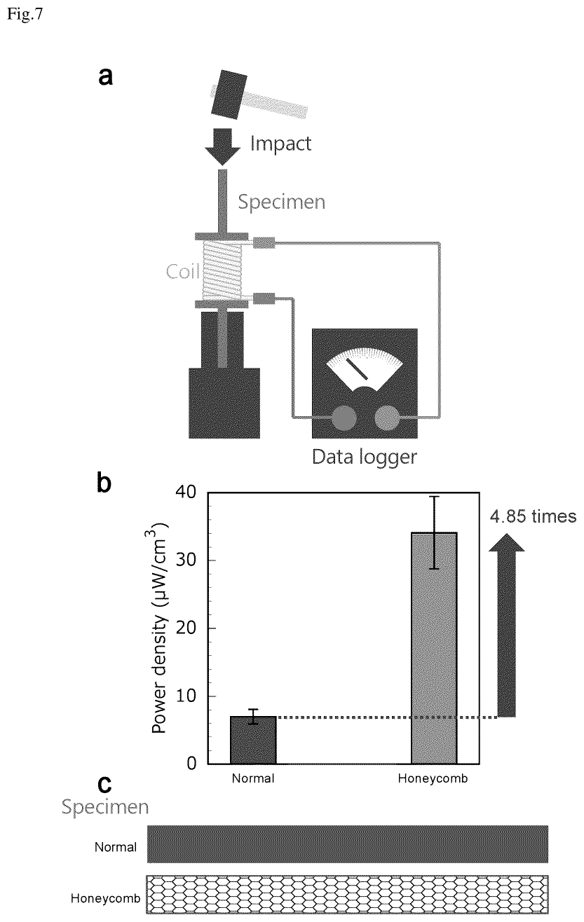

Fe49-Co49 magnetostrictive material powder (grain diameter from 37 μm to 42 μm) containing a trace of vanadium (V) was subjected to additive manufacturing into a honeycomb structure in an argon atmosphere using a metal 3D additive manufacturing machine (“SLM 280HL” manufactured by SLM Solutions GmbH, Germany). As illustrated in FIG. 7c, the produced magnetostrictive material had a honeycomb structure having multiple hexagonal-shaped holes in cross section with a maximum diameter of 1 mm to 1.5 mm.

The produced honeycomb-structured magnetostrictive material and a plate-shaped magnetostrictive material produced for comparison using the same magnetostrictive material powder were made into specimens, and compressive load was applied to the specimens by a method illustrated in FIG. 7a to obtain respective output power densities per unit volume. As a result, as illustrated in FIG. 7b, the honeycomb-structured specimen had approximately 4.85 times the output power density of the normal plate-shaped specimen.

### Example 3

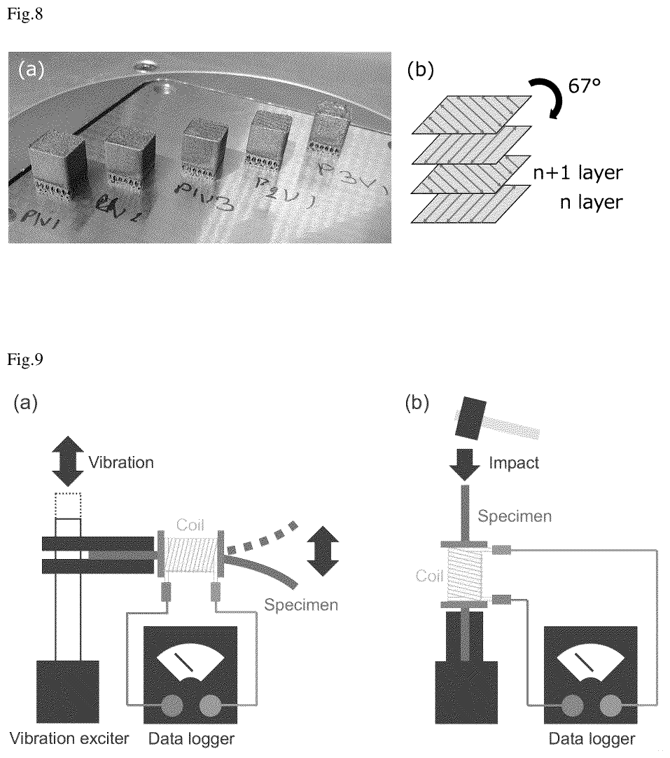

Fe52-Co48 alloy cubes (10×10×9 mm³, see FIG. 8(a)) were produced by a laser-powder-bed fusion (LPBF) process (SLM280HL, SLM Solutions Group AG) under an argon atmosphere. Fe52-Co48 alloy powder (TIZ Advanced Alloy Technology Co. Ltd.) with a D50 particle diameter of 39 μm was used. All specimens were built on an S355 steel platform.

It is known that the magnetostriction for a whole spray-cast Fe(100-x)-Cox binary series, the magnetostriction increases with an increase in Co content and reaches about 110 ppm for Co compositions between 40 at. % and 60 at. %. Fe52-Co48 is one of the reasonable ratios, and Fe—Co alloy powder with this ratio is commercially fabricated. The processing of new materials with metallic additive manufacturing (AM) technique often requires the development of process parameters, which generally include four main parameters of laser power (P), scanning speed (v), hatching distance (h), and layer thickness (t). A volume energy density (E), defined by Formula (4) below, is frequently used to compare different parameters:

E=P/vht (4)

In this example, five samples were prepared with the laser outputs and scanning speeds varied to determine the appropriate energy density. Table 4 shows experimental condition parameters of P1V1, P2V1, P3V1, P1V2, and P1V3 used for preparing the samples. A scanning method includes two border paths and a filling path composed of back-and-forth scans over a maximal length of 10 mm. For each successive slice, the scanning paths were rotated around the building direction by an angle of 67° in order to avoid path overlay (see FIG. 8(b)).

TABLE 4
Production parameters

| | Parameter name | Laser power | Scanning speed | Hatch space | Thickness | Energy density |
|---|---|---|---|---|---|---|
| | in this study | P (W) | v (mm/s) | h (mm) | t (mm) | E (J/mm³) |
| Varying power | P1V1 | 200 | 1000 | 0.08 | 0.03 | 104.2 |
| | P2V1 | 250 | 1000 | 0.08 | 0.03 | 130.2 |
| | P3V1 | 300 | 1000 | 0.08 | 0.03 | 156.3 |
| Varying velocity | P1V2 | 200 | 775 | 0.08 | 0.03 | 134.4 |
| | P1V3 | 200 | 660 | 0.08 | 0.03 | 157.8 |

Two sections of each specimen were cut along the building direction. Samples were polished using SiC paper with grit size from 600 to 4000, followed by Al₂O₃ polishing with a final grain diameter of 0.1 μm, and finally cleaned with ethanol. The porosity of the Fe52-Co48 alloy cubes was observed on two sections along the building direction using an optical microscope (Zeiss Axio Imager, Carl Zeiss Microscopy). The microstructure of each Fe52-Co48 alloy cube was evaluated using a scanning electron microscope (Zeiss Supra 40, Carl Zeiss Microscopy) and by X-ray diffraction (XRD) measurements (D8 Brucker, Brucker Corporation) using CoKα radiation. An accelerating voltage was 40 kV, and a current was 13 mA.

Furthermore, energy-dispersive X-ray (EDX) spectroscopy was used to evaluate the Fe and Co concentrations in the Fe52-Co48 alloy cubes (EDX, Brucker Corporation). Subsequently, fully dense and honeycomb Fe52-Co48 alloy plates with dimensions of 70×5×1.6 mm³ were prepared. The wall thickness and cell width of the honeycomb plates were controlled to be 250 μm and 2.5 mm, respectively. Electron backscatter diffraction (EBSD) was used to observe the fine structures of the Fe52-Co48 alloys. The crystal orientation and crystal grain diameter of the fully dense Fe52-Co48 alloy plates were evaluated using Atex software.

To investigate the vibration and impact-energy-harvesting performance of the Fe52-Co48 alloy plates, a power density, which is an output power divided by the volume of an alloy, was measured. FIG. 9 illustrates schematic diagrams of vibration and impact-energy-harvesting performance tests. A vibration generation system is composed of a shaker (ET-132, Labworks Inc., USA), a linear power amplifier (PA-151, Labworks Inc., USA) and a function generator (33250A, Agilent Technologies Inc., USA) to control the waveform and frequency of output vibration. In the example, sinusoidal vibration was employed.

Twenty-five mm from the edges of the Fe52-Co48 alloy plates (effective length of 45 mm) were fixed to the shaker and then connected with a data logger to obtain output voltages during vibration between 200 Hz and 600 Hz. For the impact-energy-harvesting test, the ones in which 25 mm from the edges of the fully dense and honeycomb Fe52-Co48 alloy plates (effective length of 45 mm) were vertically fixed to a mold were used. Three specimens were prepared for each structure.

Then, the fully dense and honeycomb Fe52-Co48 alloy plates and an impulse hammer (GK-3100, Ono Sokki Co. Ltd., Japan) were connected to a data logger (NR-500, KEYENCE Corporation, Japan) with a resistance value of 1 MΩ. Accordingly, an impact stress generated by the impulse hammer and the output voltages of the specimens can be recorded by a computer. Usually, in order to obtain a large output voltage and power, it is necessary to rotate the magnetic domain of the Fe52-Co48 alloy plate as much as possible in a coil. Therefore, experiments were conducted so that large compressive stresses would be applied to elongated plate-shaped structures. A coil resistance was 11.42 kΩ, a load resistance was 11.72 kΩ, the coil contained 28,000 turns, and a coil diameter was 0.05 mm. Before the vibration and impact-energy-harvesting tests, the resonant frequency and the optimal resistance value needed to obtain the maximum output power from the honeycomb-structured Fe52-Co48 alloy plate at high densities were first determined.

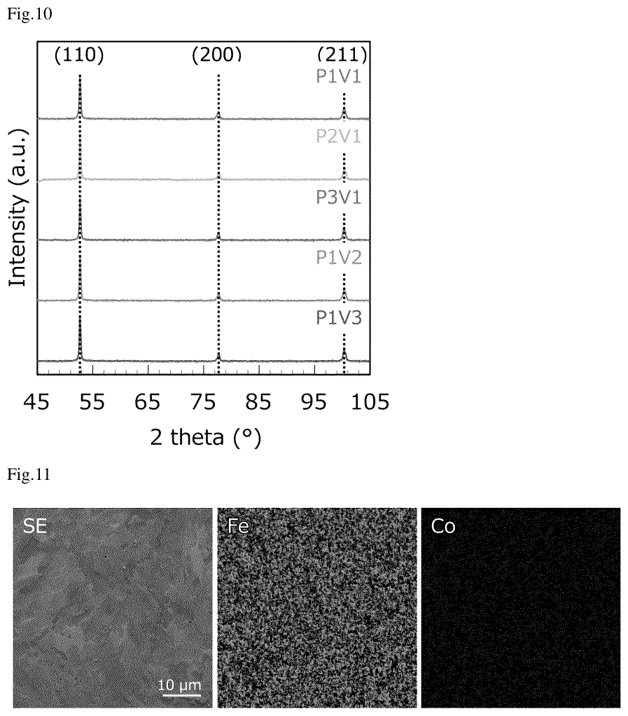

FIG. 10 illustrates XRD patterns of the Fe52-Co48 alloy cubes obtained using each production parameter. The profile of the alloy obtained using each production parameter contains three strong diffraction peaks, which correspond to (110), (200), and (211) crystal planes. The profile is composed of three strong diffraction peaks, which correspond to (110), (200) and (211) crystal planes of a body-centered cubic (bcc) phase for each process parameter. A lattice constant was estimated to be 0.2852 nm which is in close agreement with the value of 0.2855 nm of an arc melted FeCo.

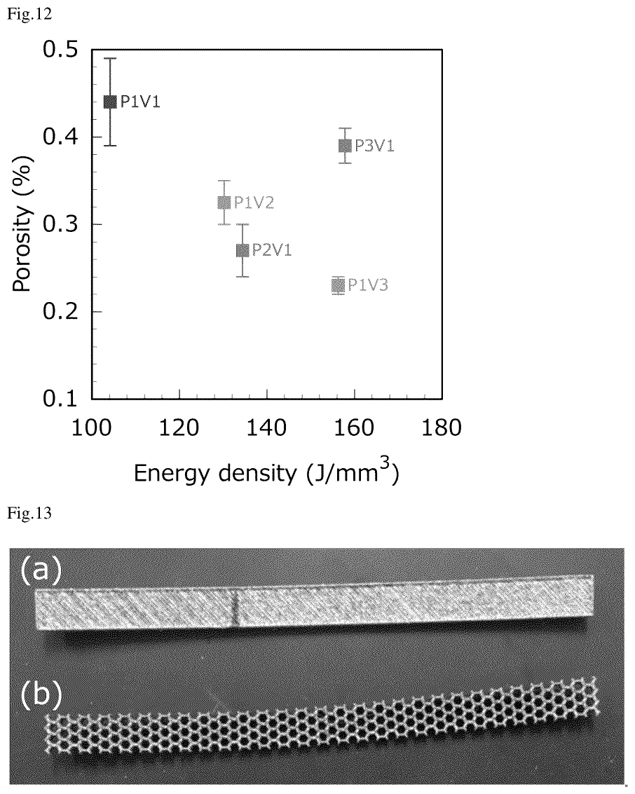

FIG. 11 illustrates a secondary electron image and EDX maps of the Fe52-Co48 alloy cube produced using the P2V1 parameters. The fine structure appears to be homogeneous, without precipitation or chemical segregation. FIG. 12 illustrates a relationship between the porosity and the energy density of the Fe52-Co48 alloy cubes produced using each parameter. In the Fe52-Co48 alloy cube produced using the P2V1 parameters, the porosity was 1.5%. The relative density of each Fe52-Co48 alloy cube exceeded 99.5%, regardless of the production parameters. The densities of the cubes tended to increase with the volume energy density, except for the case with 300 W of power, where a keyhole regime can be expected.

FIG. 13 illustrates the appearance of the Fe52-Co48 alloy plates produced using the P2V1. Both plates having a fully dense structure and a honeycomb structure could be produced using LPBF.

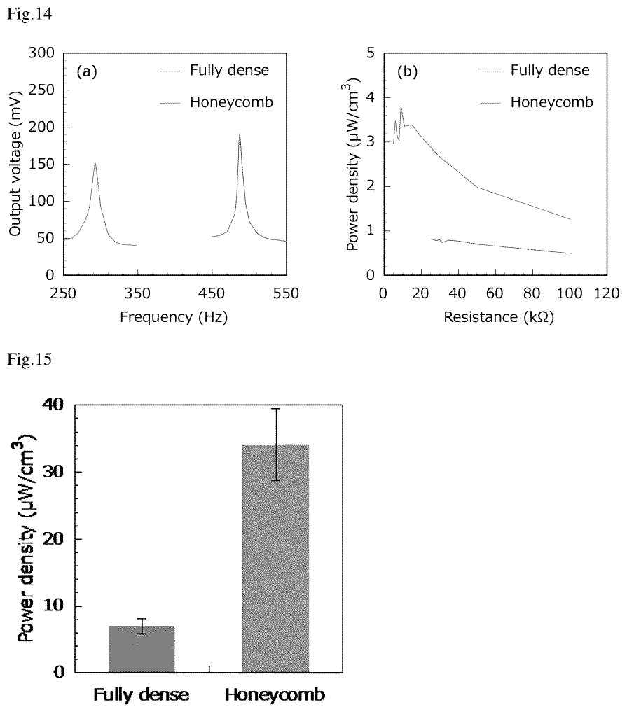

FIG. 14(a) illustrates relationships of the output voltage to the frequency of the Fe52-Co48 alloy plates in the vibration-energy-harvesting tests. The resonant frequencies of the fully dense and honeycomb-structured Fe52-Co48 alloy plates were 487 Hz and 293 Hz, respectively. This result indicates that the structural change of an Fe52-Co48 alloy plate shifts its resonant frequency, with the honeycomb structure having a lower resonant frequency than the fully dense structure. Because vibration frequencies in daily life tend to be low, vibration-energy-harvesting devices preferably have a low resonant frequency.

Additionally, a relationship of power density to resistance at these resonant frequencies were investigated (see FIG. 14(b)). As illustrated in FIG. 14(b), the honeycomb structure body exhibited a power density 4.7 times larger than that of the fully dense one in the vibration tests. It is known that the maximum output voltage of a notched FeCo/Ni-clad plate cantilever is higher than the maximum output voltage of a cantilever without a notch. It is considered that this result is attributed to the stress concentration generated by the notch. Therefore, it is highly likely that the remarkable output power density obtained from the honeycomb structure is also caused by a high-stress level.

A honeycomb-structured plate thus seems to work effectively in generating electricity from the viewpoint of both the resonant frequency and the power density. FIG. 15 illustrates the power densities of the Fe52-Co48 alloy plates in the impact-energy-harvesting tests. As illustrated in FIG. 15, the honeycomb structure body exhibited a power density 4.9 times larger than that of the fully dense structure body in the impact tests. During the impact tests, the honeycomb-structured plates did not fail.

It is well known that magnetostrictive materials can be used as particulate matter sensors by utilizing the shift in resonant frequency or output voltage. The sensitivity of a magnetostrictive particulate matter sensor is dominated by its weight. Thus, such a sensor must be lightweight to obtain high sensitivity. The honeycomb and other designed structure bodies can be used to provide both high energy-harvesting performance and high sensitivity as a particulate matter sensor.

As described above, it was found out that, as a result of evaluating the vibration and impact-energy-harvesting performance of the plate materials having a honeycomb structure, the resonant frequency shifts to a lower value with the honeycomb structure. Furthermore, the honeycomb structure bodies exhibited high power densities in the vibration tests and the impact tests. With the honeycomb structure bodies, efficient electric generation can be expected.

1. A method for producing a magnetostrictive material, comprising melting raw material powder for a magnetostrictive material by a directed energy deposition method to perform additive manufacturing.

2. The method for producing a magnetostrictive material according to claim 1, comprising melting the raw material powder by a laser or electron beam using a metal 3D additive manufacturing machine to perform additive manufacturing.

3. The method for producing a magnetostrictive material according to claim 1, comprising a step of cutting a laminated magnetostrictive material in a predetermined direction.

4. The method for producing a magnetostrictive material according to claim 1, wherein
the raw material powder is composed of an Fe—Co alloy.

5. The method for producing a magnetostrictive material according to claim 1, wherein
the raw material powder is subjected to additive manufacturing into a honeycomb structure.

6. A magnetostrictive material produced by the method for producing a magnetostrictive material according to claim 5, wherein
the magnetostrictive material has a honeycomb structure.

7. A method for producing an energy conversion member, comprising
laminating and joining one of a magnetostrictive layer formed by melting raw material powder for a magnetostrictive material by a directed energy deposition method to perform additive manufacturing and a soft magnetic material layer formed by melting raw material powder for a soft magnetic material by the directed energy deposition method to perform additive manufacturing on another.

8. A method for producing an energy conversion member, comprising
laminating and joining a magnetostrictive layer formed by melting raw material powder for a magnetostrictive material by a directed energy deposition method to perform additive manufacturing on a soft magnetic material.
